(19) United States
(12) Patent Application Publication
(10) Pub. No.: US 2025/0014967 A1
(43) Pub. Date: Jan. 9, 2025

(54) METHODS AND APPARATUS TO IMPROVE THERMAL DISSIPATION AND MECHANICAL LOADING OF INTEGRATED CIRCUIT PACKAGES

(71) Applicant: Intel Corporation, Santa Clara, CA (US)

(72) Inventors: Kyle Jordan Arrington, Gilbert, AZ (US); Prabhakar Subrahmanyam, San Jose, CA (US); Steven Adam Klein, Chandler, AZ (US); Kelly Porter Lofgreen, Phoenix, AZ (US); Joseph Blane Petrini, Gilbert, AZ (US)

(73) Assignee: Intel Corporation, Santa Clara, CA (US)

(21) Appl. No.: 18/893,576

(22) Filed: Sep. 23, 2024

(51) Int. Cl. H01L 23/473; H01L 23/40; H01L 23/42; H01R 12/85; H01R 13/52

(52) U.S. Cl. CPC H01L 23/4735; H01L 23/4093; H01L 23/42; H01R 12/85; H01R 13/5202

(57) ABSTRACT

Systems, apparatus, articles of manufacture, and methods to improve thermal dissipation and mechanical loading of integrated circuit packages are disclosed. An example apparatus includes: a socket to receive an integrated circuit package; and a plate to apply a load on the integrated circuit package towards the socket. The plate includes an internal channel to carry a coolant through the plate. The liquid coolant is to facilitate cooling of the integrated circuit package.

### BACKGROUND

The demand for greater computing power and faster computing times continues to grow. This has led to higher-density connectors on computer hardware components to transfer signals more quickly. Some processor chips (e.g., a land grid array (LGA) processor chip, a ball grid array (BGA) processor chip, a pin grid array (PGA) processor chip, etc.) are communicatively coupled to printed circuit boards (PCBs) via sockets constructed to receive and electrical couple to contacts on the processor chips. Often a heatsink or other thermal dissipation device is mechanically and thermally coupled to the processor chip on a side opposite the socket to facilitate the dissipation of heat generated by the processor chip.

### BRIEF DESCRIPTION OF THE DRAWINGS

FIG. 1-4 illustrate an example circuit system at different stages of assembly.

FIG. 5 is a simplified cross-sectional view of an example integrated loading mechanism that may be used to implement the example integrated loading mechanism of FIGS. 1-4.

FIG. 6 is a simplified cross-sectional view of another example integrated loading mechanism that may be used to implement the example integrated loading mechanism of FIGS. 1-4.

FIG. 7 is a simplified cross-sectional view of another example integrated loading mechanism that may be used to implement the example integrated loading mechanism of FIGS. 1-4.

FIG. 8 is a simplified cross-sectional view of another example integrated loading mechanism that may be used to implement the example integrated loading mechanism of FIGS. 1-4.

FIG. 9 is a simplified cross-sectional view of another example integrated loading mechanism that may be used to implement the example integrated loading mechanism of FIGS. 1-4.

FIG. 10 is a simplified cross-sectional view of another example integrated loading mechanism that may be used to implement the example integrated loading mechanism of FIGS. 1-4.

FIG. 11 is a simplified cross-sectional view of another example integrated loading mechanism that may be used to implement the example integrated loading mechanism of FIGS. 1-4.

FIG. 12 is a simplified cross-sectional view of another example integrated loading mechanism that may be used to implement the example integrated loading mechanism of FIGS. 1-4.

FIG. 13 is an exploded view of an example direct impingement cooling system constructed in accordance with teachings disclosed herein.

FIG. 14 illustrates a top perspective view of the example direct impingement cooling system of FIG. 13 in a partially assembled state with the example heat dissipating plate spaced apart from the rest of the assembly to show an underside of the plate.

FIG. 15 illustrates an example nozzle plate assembly that may be implemented in the example direct impingement cooling system of FIG. 13.

FIG. 16 is a flowchart representative of an example method to implement an example system including any of the example integrated loading mechanisms and/or any one of the example cooling systems of FIGS. 1-15.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Integrated circuit (IC) packages are often coupled to a printed circuit board via a surface mounting system, such as a land grid array (LGA). LGA connections are formed between a plurality of pins in a socket of the printed circuit board and a plurality of lands on the integrated circuit package. To facilitate an electrical connection between the pins of the printed circuit board and the lands of the integrated circuit package, some known integrated circuit packages are held in compression against the printed circuit board. In recent years, as the processing density of integrated circuit packages increases, the density of connections between integrated circuit packages and sockets accordingly increases. The increased density of connections correspondingly increases the required compressive load to mount the integrated circuit package. For instance, approximately 0.022 pounds of force (e.g., approximately 10 grams of force) is provided on a package for each pin in an associated socket to ensure consistent and reliable electrical contact between components (e.g., socket pins and LGA pads). Thus, an IC package with 5000 contacts (e.g., LGA pads) that are to connect with 5000 pins needs more than 1000 pounds of force.

The increasing density of IC packages also increases the thermal output of such packages giving rise to the need for more efficient thermal management systems to dissipate the generated heat. Typically, heat generated by an LGA package is dissipated by a heatsink thermally coupled to the package. In such scenarios, the heat generated by an LGA package initially originates from one or more semiconductor dies (also referred to herein as semiconductor chips) in the package. The heat generated by a die often must pass through a lid (e.g., an integrated heat spreader (IHS)) of the package before the heat is drawn away by the heatsink. Additionally, a first layer of thermal interface material (TIM) is usually positioned between the dies and the lid and a second layer of TIM is usually positioned between the lid and the heatsink. As such, there are three layers of material through which heat must be transferred from a die to a heatsink, resulting in thermal inefficiencies.

Simulations have shown improvements in thermal dissipation when a bare-die package is used. As used herein, a bare-die package is an IC package that does not include a lid such that the semiconductor dies are uncovered and/or exposed to the external environment (e.g., the dies are bare). In such scenarios, only one layer of TIM (and no lid) is positioned between the heatsink and the bare die. Based on the boundary conditions of the simulations, the hotspot power density of a lidded package when the maximum junction temperature (Tⱼₘₐₓ) reaches a thermal throttling limit (e.g., 100° C.) while being cooled by a high-end air-cooled heatsink is around 15 watts per square millimeter (W/mm²) By contrast, the hotspot power density of a bare-die package cooled by a similar heatsink is approximately 20 W/mm² when it reaches the thermal throttling limit. Thus, a heatsink thermally coupled to a bare die enables approximately an additional 5 W/mm² of power density before thermal throttling.

Simulated testing has further shown that significantly greater thermal efficiencies can be achieved when the air-cooled heatsink is replaced by liquid-cooled heatsink (e.g., a microchannel cold plate) thermally coupled to a bare die. Specifically, the hotspot power density of a bare-die package cooled by a liquid-cooled heatsink is well over 30 W/mm² when it reaches the thermal throttling limit. It is expected that the same or even greater thermal efficiency can be achieved to cool a bare die with a direct fluid impingement cooling system (e.g., a system that directs one or more jets of a liquid coolant directly onto the surface of the bare die) because there is no material (TIM or otherwise) between the die and the coolant.

While thermal dissipation is significantly improved when a heatsink is thermally coupled to the die(s) in a package that does not include a lid (e.g., a bare-die package) and even more so when the heatsink is liquid cooled and/or direct impingement cooling is employed, there are a number of challenges to implementing such heat dissipating systems. As already discussed above, LGA packages require significant amounts of loading force to ensure reliable contact between the package and the pins in an underlying socket. In a bare-die package, there is no lid to protect the semiconductor dies and distribute the loading force across the package. Rather, the exposed semiconductor die (e.g., the bare die) is subject to the full force of the load, which presents significant risks of damage to the die. Furthermore, there is currently no way for an end-user to couple a liquid-cooled microchannel cold plate or a direct fluid impingement cooling system to a bare-die LGA package in a reliable way (e.g., adequate loading force without damage to the die and appropriate application of TIM where needed). Further still, there is currently no infrastructure for chip developers and/or manufacturers to test bare dies with a liquid-cooled microchannel cold plate or a direct fluid impingement cooling system.

Examples disclosed herein help overcome the above challenges by enabling heat dissipating systems based on liquid-cooled cold plates or direct fluid impingement. More particularly, example heat dissipating systems are integrated into a loading mechanism that is designed to distribute the loading force across an IC package by transferring at least some of the loading force to a surface of the package substrate at locations spaced apart from (e.g., surrounding) the die. Examples disclosed herein enable end users to use custom (e.g., high performance, niche, aftermarket) TIMs, such a liquid metal for improved thermal performance. Further, examples disclosed herein enable chip developers and/or manufacturers to perform high volume testing of chips in a bare-die configuration that avoids the cost and complications of interfacing with an integrated liquid thermal solution.

Additionally, in some examples, the direct impingement cooling systems disclosed herein include a nozzle plate that is moveable relative to the rest of the heat dissipating system so as to adjust the distance between the nozzles and the surface of the bare die to be cooled. As disclosed herein, such adjustments to the nozzle height can be used to control temperature conditions during testing while maintaining other boundary conditions constant. As a result, examples disclosed herein reduce complexity and provide increased control when testing dies. While examples disclosed herein are described with reference to bare-die LGA packages, teachings disclosed herein can be suitably adapted to any type of package, whether lidded or bare, and whether inserted into a socket (LGA or otherwise) or soldered directly to a printed circuit board.

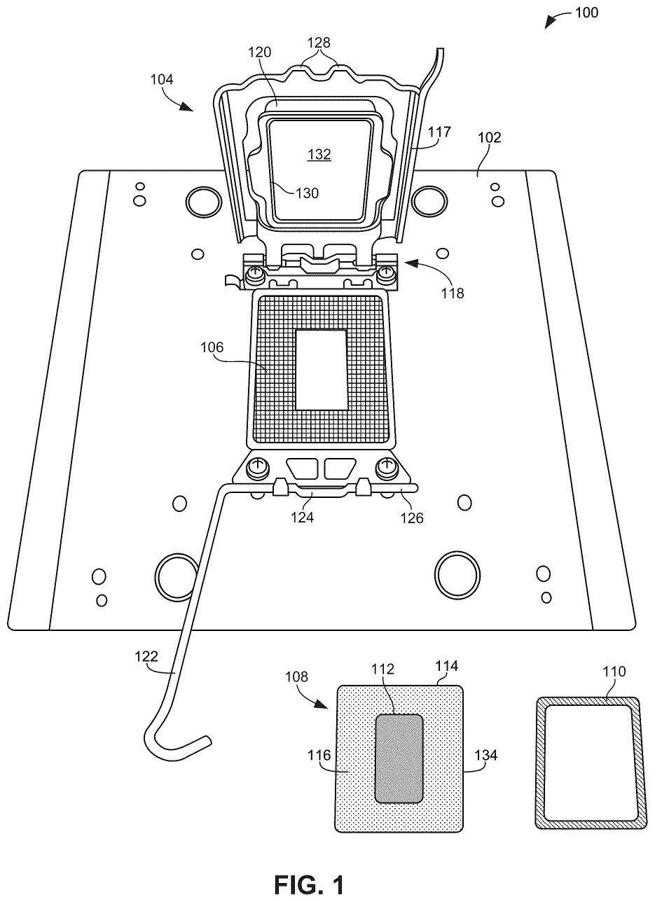

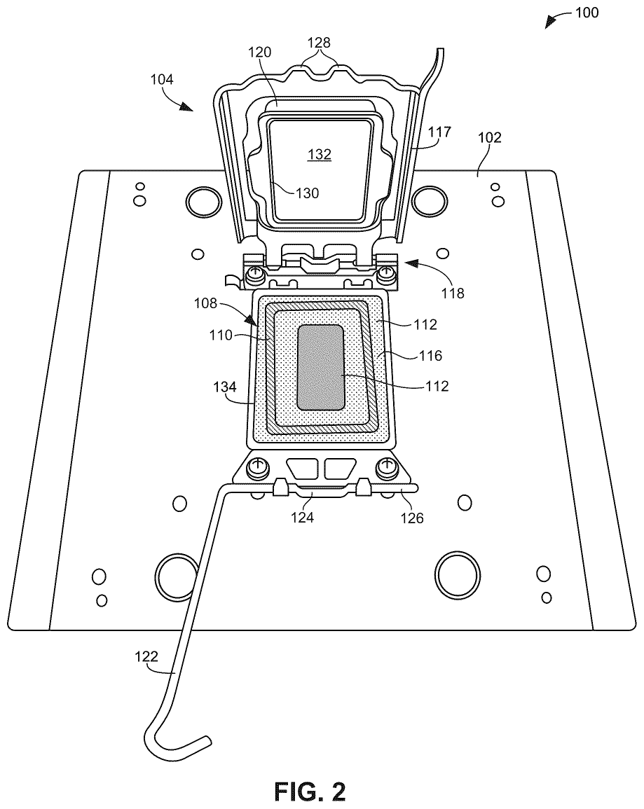

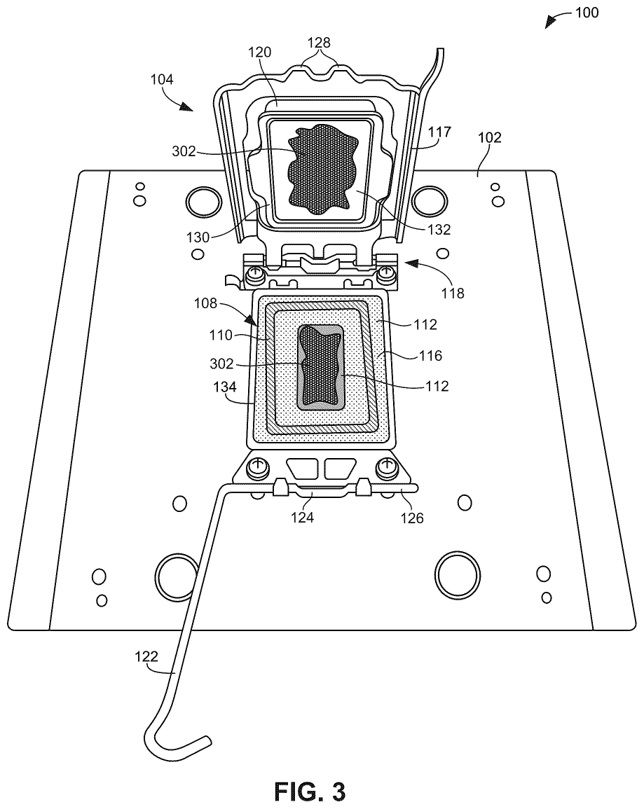

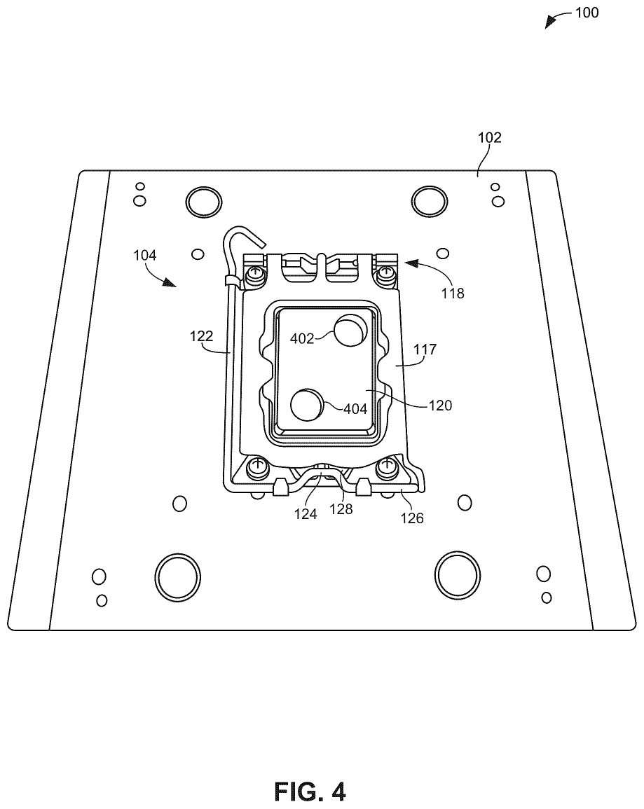

FIG. 1-4 illustrate an example circuit system 100 at different stages of assembly. The example circuit system 100 includes an example printed circuit board 102, an example integrated loading mechanism (ILM) 104, an example socket 106, an example IC package 108, and an example gasket 110 (e.g., a seal, a sealant gasket). FIG. 1 shows the circuit system 100 in a disassembled form prior to installation of the IC package 108 into the socket 106. FIG. 2 shows the circuit system 100 after installation of the IC package 108 into the socket 106 and the positioning of the gasket 110 on top of the IC package 108. FIG. 3 shows the circuit system 100 after the application of a thermal interface material 302. FIG. 4 shows the circuit system 100 with the integrated loading mechanism 104 closed over top of the IC package 108.

As shown in the illustrated example of FIG. 1, the socket 106 is mounted to the printed circuit board 102 and constructed to receive the IC package 108 (which is shown spaced apart from the socket 106 in FIG. 1). In this example, the IC package 108 is an LGA package that includes lands or pads (on the opposite side of the IC package 108 to what is shown in FIG. 1) that are to interface with corresponding pins in the socket 106. More particularly, in this example, the IC package 108 is a bare-die package. Thus, as shown, the IC package 108 includes a bare die 112 mounted to and supported by a package substrate 114. As shown in the illustrated examples, the package substrate 114 is larger than the die 112 such that an upper surface 116 of the package substrate 114 is exposed adjacent to and/or surrounding the die 112.

While the example IC package 108 is shown as including a single die 112, in other examples, the IC package 108 includes two or more dies. Additionally or alternatively, in some examples, the IC package 108 includes a lid (e.g., an integrated heat spreader (IHS)) that covers the die 112 (or multiple dies). Further, although the IC package 108 is described as an LGA package, in other examples, the IC package 108 can be a different type of package (e.g., a BGA package, a PGA package, etc.) to be received into a correspondingly different type of socket. In some examples, the IC package 108 is surface mounted (e.g., via solder connections) directly on to the printed circuit board 102 and the socket 106 is omitted.

As shown in the illustrated example, the integrated loading mechanism 104 is coupled to the printed circuit board 102 adjacent to the socket 106. More particularly, in this example, the integrated loading mechanism 104 includes an example frame 117 that is rotatably coupled to the printed circuit board 102 via an example hinge 118. In some examples, the hinge 118 is omitted and the frame 117 can be coupled to the printed circuit board using other means (e.g., threaded fasteners, etc.). As shown, the frame 117 includes and/or supports a heat dissipating plate 120 (e.g., a heat dissipating system, a heat dissipating block, a load block, etc.). As its name implies, the heat dissipating plate 120 is a plate that facilitates the dissipation of heat from the IC package 108. In this example, the plate 120 is a liquid-cooled heatsink (e.g., a microchannel cold plate). In other examples, the plate 120 includes a nozzle plate for direct impingement cooling. The heat dissipating plate 120 is also referred to herein as a load block because, as discussed further below, the plate 120 (e.g., the load block) is a block that applies a load on the IC package 108 to urge the IC package 108 towards the socket 106, thereby ensuring reliable connections between contacts (e.g., lands or pads) on the IC package 108 and pins in the socket 106.

The hinge 118 of the illustrated example enables the frame 117 to rotate between an open position away from the socket 106 (as shown in FIG. 1-3) and a closed position in which the plate 120 is positioned over top of the socket 106 (as shown in FIG. 4). In some examples, the frame 117 is held in place in the closed position by the rotation of an arm 122 of the integrated loading mechanism 104. The arm 122 is constructed to rotate between a released position (as shown in FIGS. 1-3) and a loading position (as shown in FIG. 4). As the arm 122 is rotated to the loading position, a bent portion 124 of an associated bar 126 is rotated to press down on the frame 117. Specifically, in this example, the bent portion 124 of the bar 126 presses down on one or more tabs 128 on the frame 117 distal to the hinge 118. The arm 122 and the associated bent portion 124 of the bar 126 function as a spring (e.g., a torsion spring) to urge the frame 117 towards the printed circuit board 102 and, thus, the heat dissipating plate 120 towards the IC package 108 disposed within the socket 106. In other examples, the integrated loading mechanism 104 can include any other suitable type of spring(s) (e.g., a compression spring, an extension spring, a coil spring, a flat spring, a Belleville washer, etc.) that may be loaded (e.g., compressed, extended, torqued, turned, etc.) to urge the frame 117 and the associated plate 120 towards the IC package 108. In other examples, different mechanisms other than springs can additionally or alternatively be used to urge the frame 117 and the plate 120 towards the IC package 108. For instance, in some examples, threaded fastener can be used to generate the loading force that acts on the IC package 108. In some examples, the urging of the frame 117 and plate 120 towards the IC package 108 is what provides the loading on the IC package 108 to ensure reliable contact with the underlying pins in the socket 106.

In some examples, to reduce (e.g., prevent) damage to the bare die 112 on the IC package 108, the gasket 110 can be positioned between the upper surface 116 of the substrate 114 of the IC package and the plate 120 to absorb (e.g., via deformation) at least some of the force from the frame 117 as it is closed and loaded by the arm 122. Thus, in some examples, the gasket 110 includes a resilient material (e.g., an elastic polymer). Further, in some examples, at least some of the force acting on the gasket 110 is transferred to the substrate 114, thereby distributing at least some of the load from the plate 120 away from the die 112. In some examples, a separate portion of the load from the plate 120 is applied directly to the die 112. In some examples, the proportion of the load that is applied directly to the die 112 relative to the proportion that is absorbed by the gasket 110 and/or passed through the gasket 110 to the substrate 114 can be adjusted by modifying the thickness (e.g., height) and/or the durometer or stiffness of the gasket 110. In some examples, the design of these characteristics of the gasket 110 depends on the circumstances of the application and involves a tradeoff between reduced pressure on the die (to protect the die from damage) and achieving adequate loading of the die (to enable efficient heat dissipation).

In some examples, the gasket 110 is dimensioned so that the plate 120 contacts the gasket 110 before contacting the die 112 to reduce the risk of damage to the die 112. Thus, in some examples, the gasket 110 has a thickness (e.g., height) greater than the thickness of the die 112. In other examples, the thickness of the gasket 110 is equal to or less than the thickness of the die 112. However, in some such examples, the plate 120 still contacts the gasket 110 before contacting the die 112 based on a protruding lip 130 (e.g., a protruding ridge) on the plate 120 that extends towards and comes into contact with the gasket 110. That is, as shown in the illustrated example, the protruding lip 130 is located adjacent the perimeter or outer edge of the plate 120 and extends (e.g., protrudes) from a recessed surface 132 of the plate 120 located in the central region of the plate 120. When the plate 120 is closed on top of the IC package 108, the lip 130 aligns with the gasket 110 and the recessed surface 132 aligns with the die 112. In some examples, the gasket 110 and the protruding lip 130 collectively span (e.g., have a combined thickness corresponding to) a first distance from the recessed surface that is greater than the thickness of the die 112. In some examples, the remaining gap between the die 112 and the recessed surface 132 corresponds to a second distance that is dimensioned to permit the application of the thermal interface material 302 between the die 112 and the recessed surface 132 of the plate 120. In some examples, as shown in FIG. 3, the thermal interface material 302 is added to both the die 112 and the recessed surface 132. In such examples, the different portions of the thermal interface material 302 combine once the integrated loading mechanism 104 is closed, as shown in FIG. 4. In other instances, the thermal interface material 302 can be added exclusively to the die 112 or exclusively to the recessed surface 132 before closing the assembly.

As shown in the illustrated example of FIG. 1, the gasket 110 is detached and separate from the other components of the circuit system 100. Thus, as shown in FIG. 2, the gasket 110 is manually installed in place by resting on top of the IC package 108 after the IC package 108 is inserted into the socket 106. In other examples, the gasket 110 is affixed (e.g., with an adhesive) in place onto the substrate 114 of the IC package 108. In some examples, the gasket 110 is affixed directly to the surface 116 of the substrate 114. In some examples, the gasket 110 can be affixed to a stiffener that is itself affixed to the surface of the substrate 114. In some examples, the gasket 110 is affixed to the plate 120 (e.g., affixed along the protruding lip 130). As shown most clearly in FIG. 2, the gasket 110 is dimensioned to surround the die 112 and to be closer to a perimeter 134 (e.g., outer edge) of the IC package 108 (e.g., the perimeter of the substrate 114) than the die 112 is to the perimeter 134.

As shown in the illustrated example of FIG. 4, a backside (e.g., an outer side) of the heat dissipating plate 120 includes a first opening (e.g., hole, orifice, port) corresponding to a fluid inlet 402 and a second opening (e.g., hole, orifice, port) corresponding to a fluid outlet 404. In some examples, there is more than one inlet 402 and/or more than one outlet 404. In some examples, the inlet 402 is fluidly coupled to the outlet 404 via one or more internal channels (e.g., fluid channels) within the plate 120 that are to carry a liquid coolant through the plate (e.g., from the inlet 402 to the outlet 404). In this manner, the coolant is able to draw away heat from the die 112 to which the plate 120 is thermally coupled.

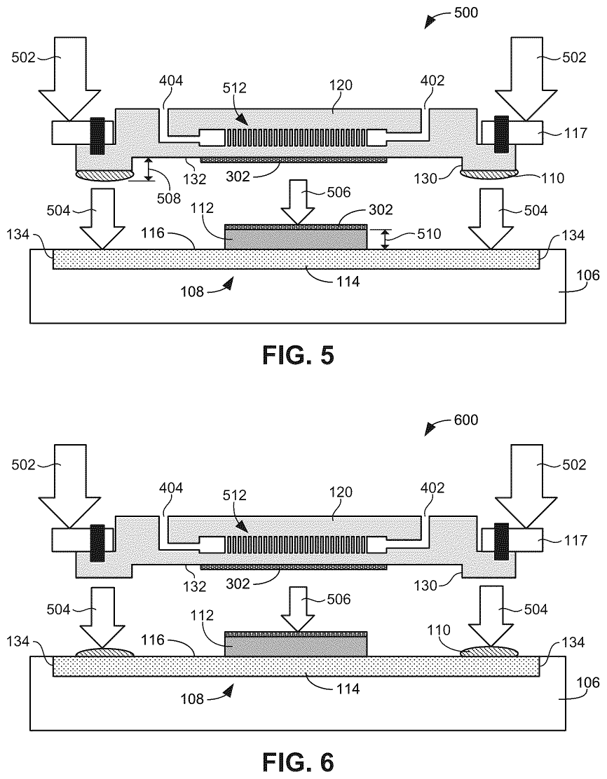

FIG. 5 is a simplified cross-sectional view of an example integrated loading mechanism 500 that may be used to implement the example integrated loading mechanism 104 of FIGS. 1-4. For purposes of explanation, the features shown in FIG. 5 that are the same or similar to corresponding features in FIGS. 1-4 are identified by the same reference numbers. Further, the description of such features described above in connection with FIGS. 1-4 applies similarly with respect to the corresponding features in FIG. 5 except as noted or otherwise made clear from the context. However, in some examples, any of the features shown in FIG. 5 can be modified and/or implemented in any suitable manner different from what is shown in FIGS. 1-4.

As shown in the illustrated example of FIG. 5, the integrated loading mechanism 500 includes the heat dissipating plate 120 that is coupled to and supported by the frame 117 to which a loading force 502 is applied (e.g., via one or more springs, via one or more threaded fasteners, etc.). In this example, the loading force 502 passes from the frame 117 and associated plate 120 to the IC package 108. More particularly, as shown in the illustrated example, the loading force 502 is distributed across the IC package 108 with a first portion 504 applied to the upper surface 116 of the substrate 114 of the IC package 108 adjacent the perimeter 134 of the IC package 108. In this example, the first portion 504 of the loading force 502 passes through the gasket 110 that is affixed to the protruding lip 130 of the plate 120. A second portion 506 of the loading force 502 is applied to the die 112 of the IC package 108. More particularly, in this example, the recessed surface 132 interfaces with top surface of the die 112 through a layer of thermal interface material 302. In the illustrated example of FIG. 5, two separate portions of the thermal interface material 302 are shown with one portion on the die 112 and one portion on the recessed surface 132 (similar to what is shown in FIG. 3). However, as discussed above, once the plate 120 is pressed against the IC package 108, the separate portions will combine into a single layer of thermal interface material 302. In some examples, the thickness of the final thermal interface material 302 corresponds to a size of the gap between the top surface of the die 112 and the recessed surface 132 of the heat dissipating plate 120. That is, in some examples, the distance of this gap corresponds to a difference between (i) a distance 508 corresponding to the combined thickness (e.g., height) of the gasket 110 and the protruding lip 130 and (ii) a thickness 510 of the die 112.

In this example, the heat dissipating plate 120 is a cold plate that includes an array of internal channels 512 (e.g., microchannels, fluid channels) between the inlet 402 and the outlet 404. A liquid coolant is provided to the inlet 402 and passes through the microchannels 512 before being removed via the outlet 404. As the coolant passes through the microchannels 512, the coolant draws away (e.g., helps to dissipate) heat generated by the die 112.

FIG. 6 is a simplified cross-sectional view of another example integrated loading mechanism 600 that may be used to implement the example integrated loading mechanism 104 of FIGS. 1-4. The example integrated loading mechanism 600 of FIG. 6 is substantially the same as the example integrated loading mechanism 500 of FIG. 5 except as noted below and/or otherwise made clear from the context. Accordingly, the features shown in FIG. 6 that are the same or similar to corresponding features in FIG. 5 are identified by the same reference numbers. Further, the description of such features described above in connection with FIG. 5 (and, by extension, FIGS. 1-4) applies similarly with respect to the corresponding features in FIG. 6. The example of FIG. 6 differs from the example of FIG. 5 in that the gasket 110 is affixed to the substrate 114 of the IC package 108 (either directly or with a stiffener disposed therebetween) rather than to the heat dissipating plate 120.

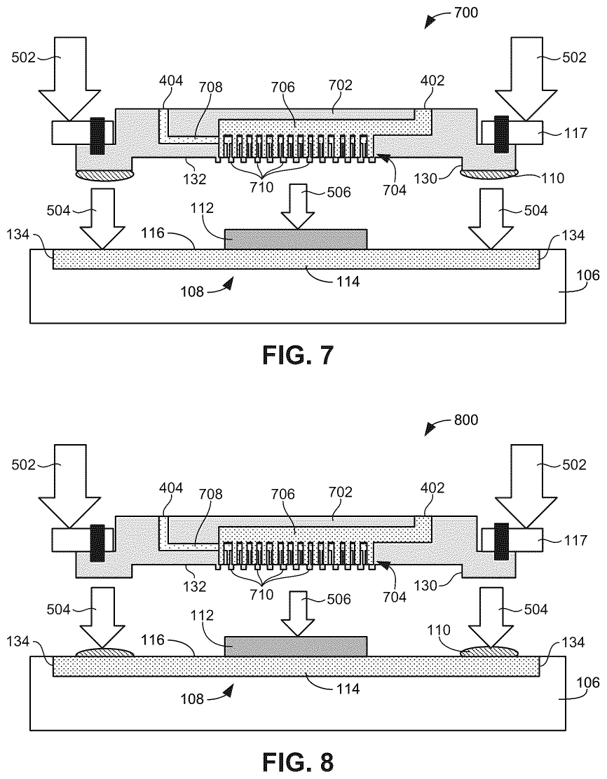

FIG. 7 is a simplified cross-sectional view of another example integrated loading mechanism 700 that may be used to implement the example integrated loading mechanism 104 of FIGS. 1-4. The example integrated loading mechanism 700 of FIG. 7 is substantially the same as the example integrated loading mechanism 500 of FIG. 5 except as noted below and/or otherwise made clear from the context. Accordingly, the features shown in FIG. 7 that are the same or similar to corresponding features in FIG. 5 are identified by the same reference numbers. Further, the description of such features described above in connection with FIG. 5 (and, by extension, FIGS. 1-4) applies similarly with respect to the corresponding features in FIG. 7.

The example of FIG. 7 differs from the example of FIG. 5 in that a different heat dissipating plate 702 (e.g., a heat dissipating system, a heat dissipating block, a load block, etc.) is employed. Whereas the heat dissipating plate 120 of FIG. 5 is shown and described as a microchannel cold plate, the heat dissipating plate 702 of FIG. 7 includes and/or defines a nozzle plate for direct impingement cooling of the die 112. That is, in the example of FIG. 7, the plate 702 includes and/or supports an array of nozzles 704 distributed along the recessed surface 132. In some examples, a first internal channel 706 (e.g., fluid channel) within the plate 702 carries coolant from the inlet 402 to the nozzles, whereupon the coolant is sprayed onto the die 112. As the coolant interacts with the die 112, the coolant heats up by drawing heat away from the die 112. Thereafter, in some examples, the heated coolant is passed back through a second internal channel 708 (e.g., fluid channel) of the plate 702 and removed (e.g., for subsequent cooling and reuse) via the outlet 404. In this example, the gasket 110 is designed to provide a hermetic seal around the die 112 so that the coolant does not leak out. In some examples, more than one gasket or seal can be used to reduce (e.g., prevent) leakage of the coolant.

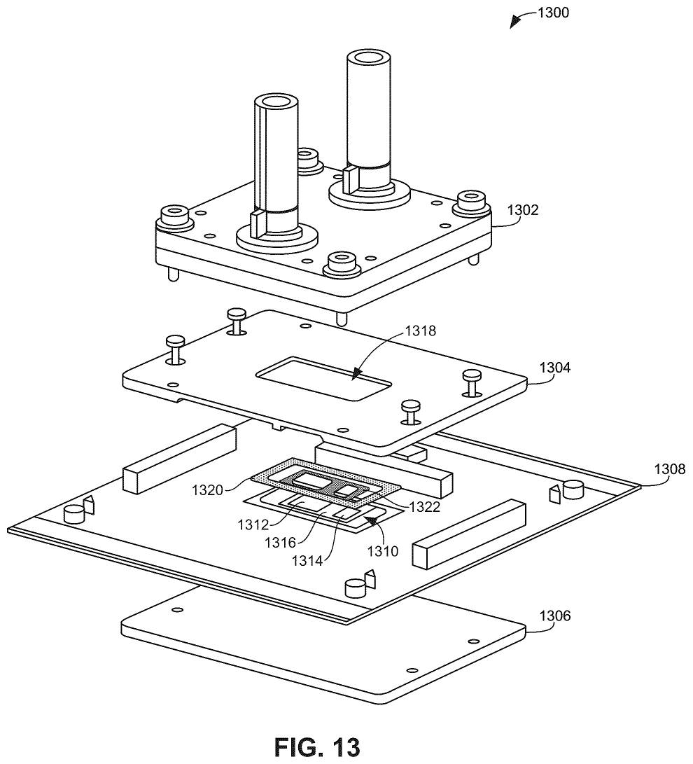

In this example, there is no need for any thermal interface material because heat transfer away from the die 112 is achieved by direct impingement of the coolant on the die 112. In some examples, the array of nozzles 704 (e.g., and the associated recessed surface 132) are spaced apart from the die 112 by a suitable distance to ensure jet streams of the coolant from the nozzles 704 adequately spray onto the die 112. In some examples, this distance may be different than the distance of the gap for the thermal interface material 302 discussed above in connection with FIG. 5. Accordingly, in some examples, the dimensions of the gasket 110 and/or the protruding lip 130 may differ in the example of FIG. 7 relative to the example of FIG. 5. In some examples, as discussed in more detail below in connection with FIGS. 13-15, the array of nozzles 704 are moveable relative to the die 112 so that the distance between the two can be adjusted and/or controlled.

In some examples, one or more standoffs 710 protrude away from the recessed surface 132 toward the die 112. In some such examples, the standoffs are dimensioned to span the gap between the recessed surface 132 and the top surface of the die 112. Thus, in such examples, the standoffs 710 interface with the die 112 when the plate 702 is urged against the IC package 108. The standoffs 710 enable the second portion 506 of the loading force 502 to be applied to the die 112 while maintaining a distance between the die 112 and the nozzles 704 to spray the coolant towards the die 112. In some examples, the standoffs 710 are omitted such that no structural components extend across the gap between the recessed surface 132 and the die 112. In such examples, the second portion 506 of the load applied to IC package 108 goes to zero and the first portion 504 corresponds to the full amount of the load.

FIG. 8 is a simplified cross-sectional view of another example integrated loading mechanism 800 that may be used to implement the example integrated loading mechanism 104 of FIGS. 1-4. The example integrated loading mechanism 800 of FIG. 8 is substantially the same as the example integrated loading mechanism 700 of FIG. 7 except as noted below and/or otherwise made clear from the context. Accordingly, the features shown in FIG. 8 that are the same or similar to corresponding features in FIG. 7 are identified by the same reference numbers. Further, the description of such features described above in connection with FIG. 7 (and, by extension, FIGS. 1-5) applies similarly with respect to the corresponding features in FIG. 8. The example of FIG. 8 differs from the example of FIG. 7 in that the gasket 110 is affixed to the substrate 114 of the IC package 108 (either directly or with a stiffener disposed therebetween) rather than to the heat dissipating plate 702.

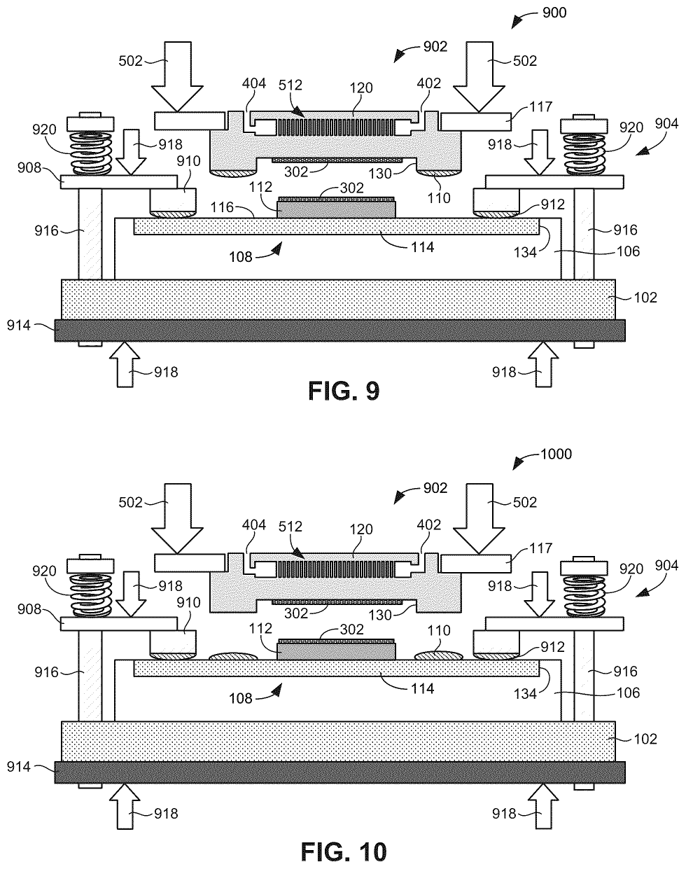

FIG. 9 is a simplified cross-sectional view of another example integrated loading mechanism 900 that may be used to implement the example integrated loading mechanism 104 of FIGS. 1-4. The example integrated loading mechanism 900 of FIG. 9 implements a two-part loading system that provides two separate load sources for two separate loads acting on the IC package 108. In this example, the first load source corresponds to a central loading mechanism 902 that is the same or similar to the integrated loading mechanism 500 of FIG. 5 except as noted below and/or otherwise made clear from the context. Accordingly, the features shown in FIG. 9 that are the same or similar to corresponding features in FIG. 5 are identified by the same reference numbers. Further, the description of such features described above in connection with FIG. 5 (and, by extension, FIGS. 1-4) applies similarly with respect to the corresponding features in FIG. 9. Thus, the load from the first load source (corresponding to the central loading mechanism 902) corresponds to the load force 502 shown in FIG. 5

The example central loading mechanism 902 of FIG. 9 differs from the example integrated loading mechanism 500 of FIG. 5 in that the protruding lip 130 of the heat dissipating plate 120 (to which the gasket 110 is affixed) is closer to the bare die 112 relative to the outer perimeter 134 of the substrate 114 of the IC package 108. As a result, a larger portion of the substrate 114 is exposed beyond the heat dissipating plate 120. The relatively large portion of the substrate 114 exposed beyond the plate 120 provides room for the second load source to interact with the substrate 114 of the IC package 108. More particularly, in this example, the second load source corresponds to an example peripheral loading mechanism 904. The example peripheral loading mechanism 904 includes a clamp plate 908 that supports or carries a frame 910 (e.g., a stiffener, a picture frame stiffener). In some examples, another gasket 912 (similar to or different from the gasket 110) is affixed to the frame 910 to directly interface with the substrate 114 of the IC package 108 (or a stiffener on the substrate 114).

In the illustrated example, the frame 910 is dimensioned to surround the bare die 112 adjacent to the perimeter 134 (e.g., along the periphery) of the substrate 114 of the IC package 108. More particularly, in this example, the frame 910 is dimensioned large enough to also surround the heat dissipating plate 120 of the example central loading mechanism 902. That is, in the illustrated example of FIG. 9, the heat dissipating plate 120 contacts the IC package 108 by extending through the frame 910 of the peripheral loading mechanism 904.

The example peripheral loading mechanism 904 includes a back plate 914 positioned on a backside of the circuit board 102 (e.g., the side opposite to which the socket 106 is mounted). In some examples, the clamp plate 908 (and the associated frame 910) and the back plate 914 are urged toward one another by one or more fasteners 916 (e.g., threaded fasteners) extending therebetween to create a compressive loading force 918. This compressive loading force 918 corresponds to the second load on the IC package 108 that is separate and independent of the first loading force 502 from the central loading mechanism 902.

In some examples, the fasteners 916 are spring loaded. That is, as shown in FIG. 9, the compressive loading force 918 is generated from compression of associated springs 920 (e.g., helical springs) based on the tightening of the fasteners 916. In some examples, the springs 920 reduce the stiffness with which the compressive loading force 918 is applied to the IC package 108 to account for some tolerance errors for more consistent application of loading forces and/or to absorb vibrations. Thus, in some examples, the integrated loading mechanism 900 includes a first spring (e.g., the arm 122 and the associated bent portion 124 of the bar 126 as discussed above in connection with FIGS. 1-4) that produces a first load (e.g., the loading force 502) applied by the heat dissipating plate 120 to the IC package 108, and a second spring (e.g., the springs 920 associated with the fasteners 916) to produce a second load (e.g., the compressive loading force 918) applied to the IC package 108. In some such examples, the second load is applied closer to the outer perimeter 134 of the IC package 108 than where the first load is applied. In some examples, the second load (e.g., the compressive loading force 918) is greater than the first load (e.g., the loading force 502) to reduce the risk of damage to the bare die 112 while still ensuring adequate loading of the IC package 108 is provided to achieve a reliable connection between the IC package 108 and the socket 106. In other examples, the second load is less than or equal to the first load. In some examples, the springs 920 are omitted such that the compressive loading force 918 is directly based on how tight the fasteners 916 are tightened.

FIG. 10 is a simplified cross-sectional view of another example integrated loading mechanism 1000 that may be used to implement the example integrated loading mechanism 104 of FIGS. 1-4. The example integrated loading mechanism 1000 of FIG. 10 is substantially the same as the example integrated loading mechanism 900 of FIG. 9 except as noted below and/or otherwise made clear from the context. Accordingly, the features shown in FIG. 10 that are the same or similar to corresponding features in FIG. 9 are identified by the same reference numbers. Further, the description of such features described above in connection with FIG. 9 (and, by extension, FIGS. 1-5) applies similarly with respect to the corresponding features in FIG. 10. The example of FIG. 10 differs from the example of FIG. 9 in that the gasket 110 is affixed to the substrate 114 of the IC package 108 (either directly or with a stiffener disposed therebetween) rather than the heat dissipating plate 120.

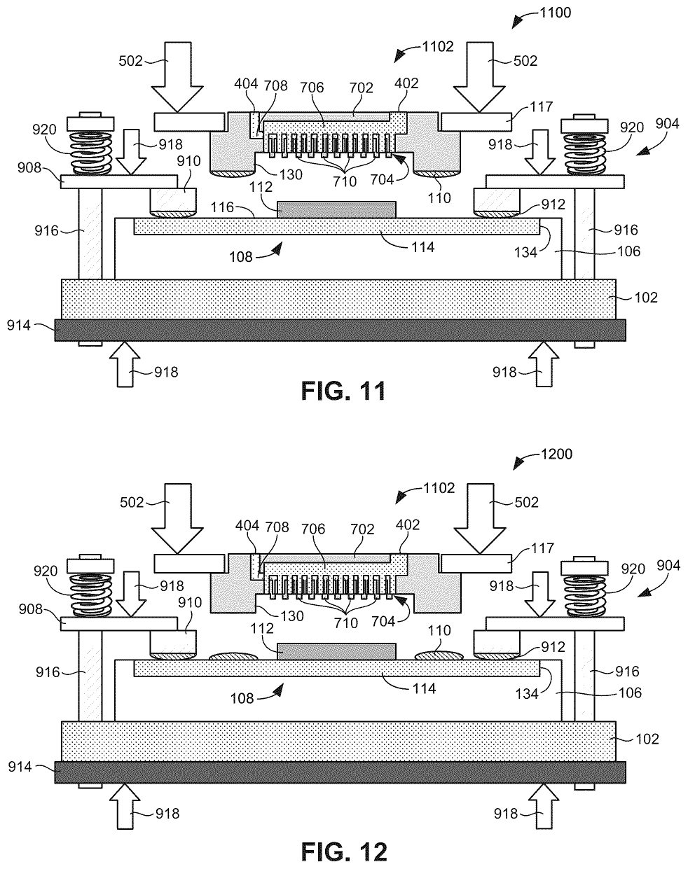

FIG. 11 is a simplified cross-sectional view of another example integrated loading mechanism 1100 that may be used to implement the example integrated loading mechanism 104 of FIGS. 1-4. The example integrated loading mechanism 1100 of FIG. 11 is substantially the same as the example integrated loading mechanism 900 of FIG. 9 except as noted below and/or otherwise made clear from the context. Accordingly, the features shown in FIG. 11 that are the same or similar to corresponding features in FIG. 9 are identified by the same reference numbers. Further, the description of such features described above in connection with FIG. 9 (and, by extension, FIGS. 1-5) applies similarly with respect to the corresponding features in FIG. 11.

The example of FIG. 11 differs from the example of FIG. 9 in that a different central loading mechanism 1102 is employed. More particularly, in this example, the central loading mechanism 1102 includes a heat dissipating plate 702 that is the same or similar to what is shown in FIG. 7 except that the protruding lip of the heat dissipating plate 120 is closer to the bare die 112 relative to the outer perimeter 134 of the substrate 114 of the IC package 108. As a result, a larger portion of the substrate 114 is exposed beyond the heat dissipating plate 120 to enable the peripheral loading mechanism 904 to interface with (e.g., push against) the substrate 114.

FIG. 12 is a simplified cross-sectional view of another example integrated loading mechanism 1200 that may be used to implement the example integrated loading mechanism 104 of FIGS. 1-4. The example integrated loading mechanism 1200 of FIG. 12 is substantially the same as the example integrated loading mechanism 1100 of FIG. 11 except as noted below and/or otherwise made clear from the context. Accordingly, the features shown in FIG. 12 that are the same or similar to corresponding features in FIG. 11 are identified by the same reference numbers. Further, the description of such features described above in connection with FIG. 11 (and, by extension, FIGS. 1-5 and 9) applies similarly with respect to the corresponding features in FIG. 12. The example of FIG. 12 differs from the example of FIG. 11 in that the gasket 110 is affixed to the substrate 114 of the IC package 108 (either directly or with a stiffener disposed therebetween) rather than the heat dissipating plate 702.

FIG. 13 is an exploded view of an example direct impingement cooling system 1300 constructed in accordance with teachings disclosed herein. The example direct impingement cooling system 1300 includes an example heat dissipating plate 1302 (e.g., a heat dissipating system, a heat dissipating block, a load block, etc.), an example clamp plate 1304, and an example back plate 1306 that are to be coupled to an example circuit board 1308 that is carrying and/or supporting an IC package 1310. More particularly, in this example, the IC package 1310 includes an example first semiconductor die 1312 and an example second semiconductor die 1314 mounted to an example package substrate 1316. In other examples, the IC package 1310 includes only one die. In other examples, the IC package 1310 includes more than two dies.

In some examples, the example direct impingement cooling system 1300 may be implemented in combination with any of the example integrated loading mechanism 700, 800, 1100, 1200 of FIGS. 7, 8, 11, and/or 12. That is, in some examples, the example heat dissipating plate 1302 is the same or similar to the example heat dissipating plate 702 of FIGS. 7, 8, 11, and/or 12 with internal channels (e.g., similar to the channels 706, 708 discussed in connection with FIG. 7) to carry fluid (e.g., a coolant) to an array of nozzles on a nozzle plate (e g, similar to the array of nozzles 704 discussed in connection with FIG. 7). In such examples, the IC package 1310 is inserted into a socket (e.g., the socket 106) on the circuit board 1308 and urged into contact with pins in the socket by a protruding lip on the heat dissipating plate 1302. Alternatively, the example direct impingement cooling system 1300 may be implemented independent of the example integrated loading mechanism 700, 800, 1100, 1200 of FIGS. 7, 8, 11, and/or 12. That is, in some examples, the IC package 1310 is loaded by the clamp plate 1304 without a separate loading force from a protruding lip of the heat dissipating plate 1302. In other words, in some examples, the heat dissipating plate 1302 is not part of an integrated loading mechanism and merely serves to cool the IC package 1310. As a result, the heat dissipating plate 1302 can be used to cool any type of IC package 1310 mounted to the circuit board 1308 in any manner (e.g., with other types of sockets other than LGA sockets (e.g., BGA socket), without a socket (e.g., direct soldering), etc.). Further, as with the other examples discussed above, the heat dissipating plate is not limited to bare-die packages but may also be used to cool lidded packages (e.g., packages including an integrated heat spreader (IHS)).

In the illustrated example, the circuit board 1308 is sandwiched between the clamp plate 1304 and the back plate 1306. The clamp plate 1304 includes an opening 1318 to provide the heat dissipating plate 1302 access to the IC package 1310 when attached over the clamp plate 1304. In some examples, the perimeter of the opening 1318 is dimensioned to interface with (e.g., be urged against) a first gasket 1320 (e.g., a first seal, an outer seal) that is positioned along the outer edge or perimeter of the IC package 1310. In other examples, the opening 1318 is larger than the first gasket 1320 to enable the heat dissipating plate 1302 to interface with (e.g., be urged against) the first gasket 1320.

As shown in the illustrated example, the first gasket 1320 surrounds both of the semiconductor dies 1312, 1314. In some examples, a second gasket 1322 (e.g., a second seal, an inner seal) is dimensioned to surround each of the dies 1312, 1314 individually. Further, the second gasket 1322 is dimensioned to be closer to the dies 1312, 1314 than the first gasket 1320 is to the dies 1312, 1314. That is, as shown in the illustrated example, the second gasket 1322 fits inside the first gasket 1320 and defines two holes or openings corresponding to the first and second dies 1312, 1314. The first gasket 1320 provides a sealant against leaks around the package substrate 1316 and the second gasket 1322 provides a sealant against leaks around each of the first and second dies 1312, 1314.

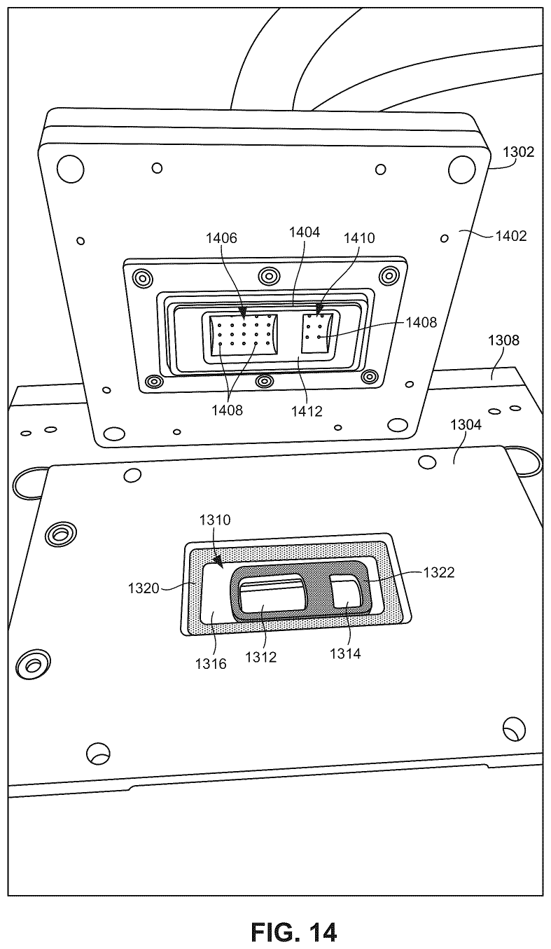

FIG. 14 illustrates a top perspective view of the example direct impingement cooling system 1300 of FIG. 13 in a partially assembled state with the heat dissipating plate 1302 spaced apart from the rest of the assembly to show an underside of the plate 1302. As shown in FIG. 14, the heat dissipating plate 1302 includes a housing 1402 and a nozzle plate 1404 attached to the housing 1402. The nozzle plate 1404 includes a first array 1406 of nozzles 1408 to direct jet streams of a coolant onto the first die 1312. The nozzle plate 1404 further includes a second array 1410 of the nozzles 1408 to direct jet streams of coolant onto the second die 1314. The nozzle arrays 1406, 1410 can include any suitable number of nozzles of any suitable size and/or shape and arranged in any suitable manner. For instance, in some examples, the nozzles are straight orifices with a nozzle outlet that is substantially equal to a nozzle inlet. In other examples, the nozzles are tapered nozzles with a nozzle outlet that is smaller than the nozzle inlet. Simulated testing has revealed that jet impingement with tapered nozzles results in a heat transfer coefficient at least twice that achieved using straight orifices. In some examples, the nozzle plate 1404 is selectively removable from the housing 1402 (e.g., via threaded fasteners) and replaceable by a different nozzle plate 1404 having different nozzles (e.g., different size, shape, number, and/or arrangement).

In some examples, the nozzle plate 1404 includes a protruding lip 1412 that surrounds both dies 1312, 1314 and is dimensioned to align with and be urged against the second gasket 1322. In some examples, as shown in FIG. 14, the protruding lip 1412 also extends between the dies 1312, 1314 to interface with a corresponding portion of the second gasket 1322, thereby isolating the first and second dies 1312, 1314 from one another.

As discussed above, direct impingement cooling on a bare die provides efficient heat transfer to cool IC packages more quickly than many other cooling methods that require heat transfer through one or more layers of TIM and/or other layers of material. Specifically, the direct impingement of cold fluid onto a bare die results in forced convection directly on the die that results in faster response times, a higher heat transfer coefficient (HTC), and a more uniform HTC gradient. Jet impingement removes large heat flux by directly striking a hot target surface (e.g., the IC package 1310) with fluids. Both simulated and actual testing reveals that adjusting the nozzle-to-silicon distance (e.g., vertical z-height) changes the flow-field characteristics and impacts the heat transfer characteristics. More particularly, as the distance between the nozzle and a die increases, there is attenuation in the velocity at the impingement on the die surface. That is, a fluid jet stream from a nozzle will hit a die at a greater velocity when the distance between the nozzle and die is smaller and will hit the die at a lower velocity as the distance increases. This change in velocity at impingement results in a change in the heat transfer coefficient of the impinging fluid. Some examples disclosed herein take advantage of this observation to enable temperature cycling test procedures of IC packages.

More particularly, in some examples, the nozzle plate 1404 is moveable relative to the housing 1402 and, thus, moveable relative to the IC package 1310 to adjust the distance between the nozzle plate 1404 and the IC package 1310. Adjusting this distance results in a change in velocity of the impinging jet streams, which results in a change in the heat transfer coefficient, thereby changing the resulting temperature of the IC package. Moreover, this change in temperature is achieved without needing to change the temperature of the coolant or the velocity (or corresponding pressure) of the coolant provided to the inlets of the nozzles. In other words, the vertical displacement (e.g., z-height) or distance of the nozzle plate can effectively be used as a boundary condition in conjunction with the inlet coolant temperature and the inlet primary velocity at the nozzles to test an IC package during temperature cycling test procedures. Further, simulated testing has shown that by adjusting these three boundary conditions (while all other conditions are identical) can result in a wide range of junction temperatures of a die generating heat at a fixed rate. Specifically, simulating nozzles spraying a hydrofluoroether (HFE) coolant at inlet temperatures ranging from −70° C. to 70° C. with associated Reynolds numbers (indicative of the nozzle inlet velocity) between 8000 and 20,000 results in a junction temperature of a semiconductor die dissipating 95W of heat that ranges from −2° C. to 120° C. depending on the distance of the nozzles from the impinging surface of the die. More particularly, the junction temperature of −2° C. is achieved based on −70° C. HFE, a Reynolds number of 8000, and a nozzle distance (z-height) that is 4 times the diameter of the nozzle outlet. By contrast, the junction temperature of 120° C. is achieved based on 70° C. HFE, a Reynolds number of 20,000, and a nozzle distance (z-height) that is 16 times the diameter of the nozzle outlet. Thus, different target temperatures for testing purposes can be achieved by adjusting the nozzle distance (e.g., by moving the nozzle plate 1404).

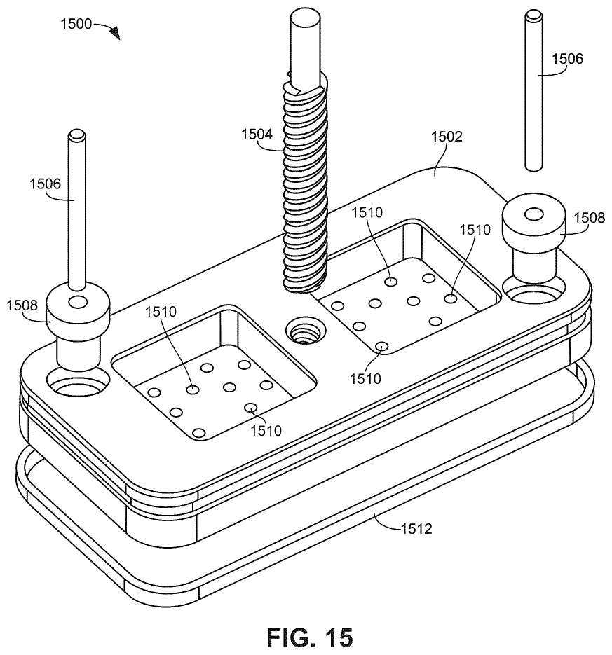

FIG. 15 illustrates an example nozzle plate assembly 1500 that may be implemented in the example direct impingement cooling system 1300 of FIG. 13. More particularly, the example nozzle plate assembly 1500 includes an example nozzle plate 1502 that may be used to implement the example nozzle plate 1404 shown in FIG. 14. Further, in this example, the nozzle plate assembly 1500 includes an actuator 1504 to cause the nozzle plate 1502 to move relative to an associated housing (e.g., the housing 1402). In this example, the actuator 1504 is a power screw that can be driven (e.g., rotated) by a motor controlled by a microcontroller. In some examples, the nozzle plate assembly 1500 includes one or more guide rods 1506 that slide along corresponding bushings 1508 to guide movement of the nozzle plate 1502 along a straight path substantially perpendicular to the face of the nozzle plate across which nozzles 1510 are distributed. Thus, as the actuator 1504 is rotated, the nozzle plate 1502 will glide (e.g., raise or lower) along the guide rods 1506, thereby adjusting the distance of the nozzles 1510 relative to an underlying IC package (e.g., the IC package 1310 of FIG. 13). In the illustrated example of FIG. 15, a stiffener 1512 is shown to represent the relative location of the underlying package. That is, in some examples, the substrate of the IC package includes the stiffener 1512 on its outer surface facing the nozzle plate 1502. In some examples, the stiffener 1512 is made from stainless steel. In some examples, the stiffener 1512 is omitted.

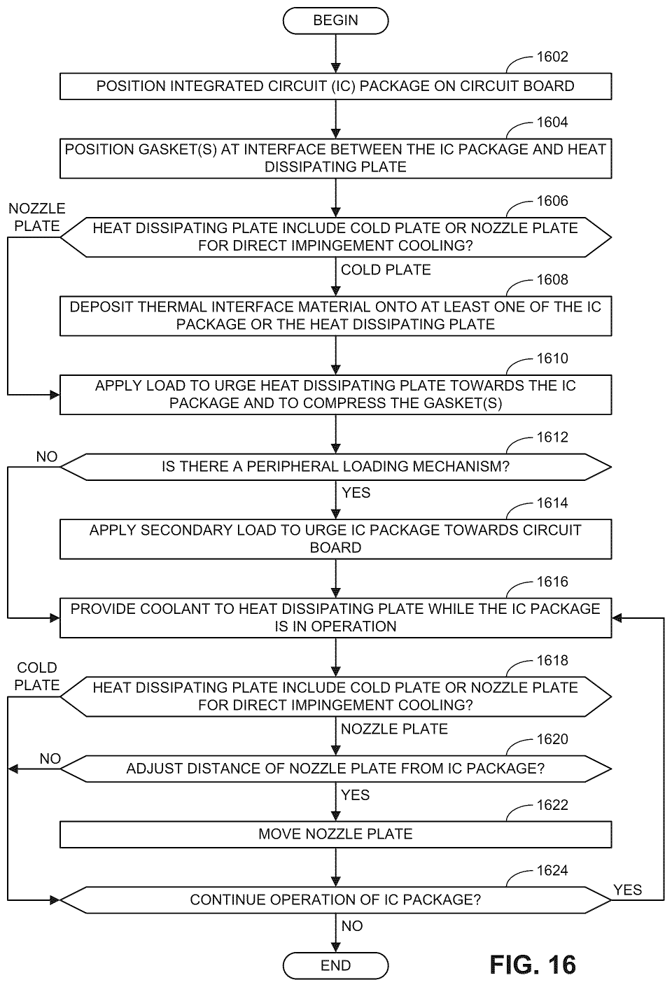

FIG. 16 is a flowchart representative of an example method to implement an example system including any of the example integrated loading mechanisms 104, 500, 600, 700, 800, 900, 1000, 1100, 1200 and/or any one of the example cooling systems 1300 of FIGS. 1-15. In some examples, some or all of the operations outlined in the example method of FIG. 16 are performed automatically by fabrication equipment that is programmed to perform the operations. Although the example method of manufacture is described with reference to the flowchart illustrated in FIG. 16, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 16 begins at block 1602 by positioning an integrated circuit (IC) package (e.g., the IC package 108, 1310) on a circuit board (e.g., the circuit board 102, 1308). In some examples, this is accomplished by inserting the IC package into a socket coupled to the circuit board. In other examples, the IC package is mounted directly to the circuit board using solder. At block 1604, the example method involves positioning one or more gasket(s) (e.g., the gaskets 110, 1320, 1322) at an interface between the IC package and a heat dissipating plate (e.g., the heat dissipating plate 120, 702, 1302). In some examples, the gasket(s) can be affixed to the IC package and/or to the heat dissipating plate in advance.

At block 1606, the example method determines whether the heat dissipating plate includes a cold plate or a nozzle plate for direct impingement cooling. If the heat dissipating plate includes a cold plate (as in the illustrated examples of FIGS. 1-6, 9, and 10), the method advances to block 1608 where thermal interface material (e.g., the thermal interface material 302) is deposited on at least one of the IC package or the heat dissipating plate. Thereafter, the method advances to block 1610. Returning to block 1606, if the heat dissipating plate includes a nozzle plate (as in the illustrated examples of FIGS. 7, 8, and 11-15), the method advances to directly block 1610. At block 1610, the example method involves applying a load (e.g., the loading force 502) to urge the heat dissipating plate towards the IC package and to compress the gasket(s).

At block 1612, the example method determines whether there is a peripheral loading mechanism (as in the illustrated examples of FIGS. 9-12). If not, the method advances to block 1616. If so, the method advances to block 1614 where a secondary load (e.g., the compressive loading force 918) is applied to urge the IC package toward the circuit board. Thereafter, the method advances to block 1616. At block 1616, the method involves providing coolant to the heat dissipating plate while the IC package is in operation.

At block 1618, the example method determines whether the heat dissipating plate includes a cold plate or a nozzle plate for direct impingement cooling. This is the same determination made at block 1606 above. If the heat dissipating plate includes the cold plate, the method advances directly to block 1624. If the heat dissipating plate includes the nozzle plate, the method advances to block 1620 to determine whether the distance of the nozzle plate from the IC package is to be adjusted. If so, the method advances to block 1622 where the nozzle plate is moved (as discussed above in connection with FIGS. 13-15). Thereafter, the method advances to block 1624. If the method determines (at block 1620) that the nozzle plate is not to be adjusted, the method advances directly to block 1624.

At block 1624, the method involves determining whether to continue operation of the IC package. If so, the method returns to block 161. Otherwise, the example method of FIG. 16 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable improved dissipation of heat generated by a semiconductor die of a socketed IC package (e.g., an LGA package) by implementing the package without a lid (e.g., a bare-die package) while protecting the bare die from damage by distributing the load applied to the package between the bare die and the package substrate surrounding the die. In some examples, heat dissipation is improved by enabling a heat dissipating plate that functions as a cold plate to thermally couple directly (e.g., via a single layer of TIM) with the bare die. In other examples, heat dissipation is improved by implementing the heat dissipating plate that supports one or more nozzles to spray jets of coolant that impinge directly on the surface of the bar die. In some examples, the bare die is protected from damage by including a gasket positioned adjacent to the die so as to be compressed between the heat dissipating plate and the substrate of the package, thereby absorbing some of the loading force applied by the heat dissipating plate. Further, in some direct impingement cooling examples, the nozzle plate is moveable relative to the IC package to adjust a distance between the nozzle(s) and the die to adjust the velocity of impingement and the corresponding heat transfer coefficient of the impinging fluid. In this manner, the temperature of the die can be controlled to target temperatures for purposes of temperature cycling tests.

Further examples and combinations thereof include the following:

Example 1 includes an apparatus comprising a socket to receive an integrated circuit package, and a plate to apply a load on the integrated circuit package towards the socket, the plate including an internal channel to carry a liquid coolant through the plate, the liquid coolant to facilitate cooling of the integrated circuit package.

Example 2 includes the apparatus of example 1, further including a gasket capable of being compressed between the plate and a substrate of the integrated circuit package.

Example 3 includes the apparatus of example 2, wherein the gasket is capable of being affixed to the plate.

Example 4 includes the apparatus of example 2, wherein the gasket is capable of being affixed to the substrate of the integrated circuit package.

Example 5 includes the apparatus of any one of examples 2-4, wherein the gasket is formed to provide a hermetic seal around a semiconductor die of the integrated circuit package when the integrated circuit package is installed between the socket and the plate.

Example 6 includes the apparatus of any one of examples 2-5, wherein the plate includes a recessed surface and a protruding lip, the gasket capable of being between the protruding lip and the substrate of the integrated circuit package, the recessed surface to align with a semiconductor die of the integrated circuit package.

Example 7 includes the apparatus of example 6, wherein the protruding lip and the gasket collectively span a first distance from the recessed surface to the substrate of the integrated circuit package, the protruding lip and the gasket dimensioned wherein the first distance is greater than a thickness of the semiconductor die by a second distance, the second distance to permit application of a thermal interface material between the semiconductor die and the recessed surface.

Example 8 includes the apparatus of any one of examples 1-7, wherein the plate is a cold plate and the internal channel is a microchannel within the cold plate.

Example 9 includes the apparatus of any one of examples 1-7, further including a nozzle on the plate, the internal channel fluidly coupled with the nozzle, the nozzle positioned to cause the coolant to directly impinge on the integrated circuit package.

Example 10 includes the apparatus of example 9, further including a standoff on the plate, the standoff to interface with a semiconductor die of the integrated circuit package.

Example 11 includes the apparatus of any one of examples 9 or 10, wherein the plate includes a housing and a nozzle plate moveable relative to the housing, the nozzle supported by the nozzle plate.

Example 12 includes the apparatus of example 11, further including an actuator to move the nozzle plate relative to the housing to adjust a distance between the nozzle and the integrated circuit package.

Example 13 includes the apparatus of any one of examples 1-12, wherein the integrated circuit package is a bare-die package.

Example 14 includes the apparatus of any one of examples 1-13, wherein the integrated circuit package is a land grid array (LGA) package.

Example 15 includes an apparatus comprising a load block removably couplable to an integrated circuit package, the load block to generate a load that presses against the integrated circuit package, the load block including a fluid channel to carry a liquid therethrough, the liquid to facilitate cooling of the integrated circuit package, and a gasket to be compressed between the load block and the integrated circuit package.

Example 16 includes the apparatus of example 15, wherein the load is a first load, the apparatus further including a first spring to produce the first load applied by the load block to the integrated circuit package, and a second spring to produce a second load applied to the integrated circuit package, the second load to be applied closer to an outer perimeter of the integrated circuit package than where the first load is to be applied.

Example 17 includes the apparatus of example 16, wherein the second load is greater than the first load.

Example 18 includes the apparatus of any one of examples 15-17, wherein the load block is to begin compressing the gasket by a first portion of the load before the load block begins applying a second portion of the load to a semiconductor chip of the integrated circuit package.

Example 19 includes an apparatus comprising a plate including at least one of (i) microchannels through which a coolant is to pass to draw away heat from the plate that is thermally coupled to an integrated circuit package or (ii) an array of nozzles to directly impinge the coolant onto the integrated circuit package, and a spring to urge the plate against the integrated circuit package.

Example 20 includes the apparatus of example 19, further including a seal to be compressed between the plate and a substrate of the integrated circuit package, the seal to be adjacent to a semiconductor chip on the substrate.

Example 21 includes a method comprising: applying a load to a plate to urge the plate towards an integrated circuit package coupled to a printed circuit board, at least a portion of the load to urge the integrated circuit package towards the printed circuit board; and providing a liquid coolant to the plate, the liquid coolant to at least one of (i) pass through microchannels in the plate to cool the plate, or (ii) to be sprayed directly onto the integrated circuit package through a nozzle on the plate.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a socket to receive an integrated circuit package; and
a plate to apply a load on the integrated circuit package towards the socket, the plate including an internal channel to carry a liquid coolant through the plate, the liquid coolant to facilitate cooling of the integrated circuit package.

2. The apparatus of claim 1, further including a gasket capable of being compressed between the plate and a substrate of the integrated circuit package.

3. The apparatus of claim 2, wherein the gasket is capable of being affixed to the plate.

4. The apparatus of claim 2, wherein the gasket is capable of being affixed to the substrate of the integrated circuit package.

5. The apparatus of claim 2, wherein the gasket is formed to provide a hermetic seal around a semiconductor die of the integrated circuit package when the integrated circuit package is installed between the socket and the plate.

6. The apparatus of claim 2, wherein the plate includes a recessed surface and a protruding lip, the gasket capable of being between the protruding lip and the substrate of the integrated circuit package, the recessed surface to align with a semiconductor die of the integrated circuit package.

7. The apparatus of claim 6, wherein the protruding lip and the gasket collectively span a first distance from the recessed surface to the substrate of the integrated circuit package, the protruding lip and the gasket dimensioned wherein the first distance is greater than a thickness of the semiconductor die by a second distance, the second distance to permit application of a thermal interface material between the semiconductor die and the recessed surface.

8. The apparatus of claim 1, wherein the plate is a cold plate and the internal channel is a microchannel within the cold plate.

9. The apparatus of claim 1, further including a nozzle on the plate, the internal channel fluidly coupled with the nozzle, the nozzle positioned to cause the coolant to directly impinge on the integrated circuit package.

10. The apparatus of claim 9, further including a standoff on the plate, the standoff to interface with a semiconductor die of the integrated circuit package.

11. The apparatus of claim 9, wherein the plate includes a housing and a nozzle plate moveable relative to the housing, the nozzle supported by the nozzle plate.

12. The apparatus of claim 11, further including an actuator to move the nozzle plate relative to the housing to adjust a distance between the nozzle and the integrated circuit package.

13. The apparatus of claim 1, wherein the integrated circuit package is a bare-die package.

14. The apparatus of claim 1, wherein the integrated circuit package is a land grid array (LGA) package.

15. An apparatus comprising:
a load block removably couplable to an integrated circuit package, the load block to generate a load that presses against the integrated circuit package, the load block including a fluid channel to carry a liquid therethrough, the liquid to facilitate cooling of the integrated circuit package; and
a gasket to be compressed between the load block and the integrated circuit package.

16. The apparatus of claim 15, wherein the load is a first load, the apparatus further including:
a first spring to produce the first load applied by the load block to the integrated circuit package; and
a second spring to produce a second load applied to the integrated circuit package, the second load to be applied closer to an outer perimeter of the integrated circuit package than where the first load is to be applied.

17. The apparatus of claim 16, wherein the second load is greater than the first load.

18. The apparatus of claim 15, wherein the load block is to begin compressing the gasket by a first portion of the load before the load block begins applying a second portion of the load to a semiconductor chip of the integrated circuit package.

19. An apparatus comprising:
a plate including at least one of (i) microchannels through which a coolant is to pass to draw away heat from the plate that is thermally coupled to an integrated circuit package or (ii) an array of nozzles to directly impinge the coolant onto the integrated circuit package; and
a spring to urge the plate against the integrated circuit package.

20. The apparatus of claim 19, further including a seal to be compressed between the plate and a substrate of the integrated circuit package, the seal to be adjacent to a semiconductor chip on the substrate.

21. (canceled)
